(19) United States
(12) Patent Application Publication
(10) Pub. No.: US 2012/0318562 A1
(43) Pub. Date: Dec. 20, 2012

(54) WORKING PANEL AND WORKING PANEL SET COMPRISING ARRAY BOARD PATTERNS

(75) Inventors: Kyu-Tae Kim, Hwaseong-si (KR); Yong-Hyun Kim, Yongin-si (KR); Jung-Chan Cho, Chuncheongnam-do (KR); Jin-San Jung, Chungcheongnam-do (KR)

(73) Assignee: SAMSUNG ELECTRONICS CO., LTD., Suwon-si (KR)

(21) Appl. No.: 13/438,363

(22) Filed: Apr. 3, 2012

(30) Foreign Application Priority Data
Jun. 20, 2011 (KR) 10-2011-0059756

(51) Int. Cl. H05K 1/02

(52) U.S. Cl. 174/250

(57) ABSTRACT

A working panel includes first array board patterns arranged in a first region and including first and second guide bar patterns facing each other and N first unit board patterns, where N is a natural number greater than or equal to 2, positioned between the first and second guide bar patterns, and second array board patterns including third and fourth guide bar patterns facing each other, and M second unit board patterns, where 1≦M<N, positioned between the third and fourth guide bar patterns.

### CROSS-REFERENCE TO RELATED APPLICATION

This U.S. patent application claims priority under 35 U.S.C. §119 to Korean Patent Application No. 10-2011-0059756 filed on Jun. 20, 2011 in the Korean Intellectual Property Office, the contents of which are herein incorporated by reference in their entirety.

### BACKGROUND

1. Field of the Invention

The present invention relates to a working panel and working panel set comprising array board patterns.

2. Description of the Related Art

A required unit board may be manufactured by processing a working panel having a plurality of unit board patterns arrayed thereon. In order to improve surface mounting technology (SMT) efficiency, the plurality of unit board patterns are consecutively arranged on the working panel. An array board pattern may include the consecutively arranged plurality of unit board patterns.

Therefore, an array board including a plurality of unit boards may be manufactured by processing the working panel having the array board pattern including the plurality of unit board patterns. In addition, the SMT process may be performed in units of array boards. After the SMT process is completed, the array boards may be divided into unit boards, respectively.

Since an array board is standardized, the number of unit boards included in the array board is fixed. Therefore, the number of unit board patterns constituting one array board pattern is also fixed and the size of an array board pattern is substantially fixed. Since the size of a working panel is also standardized, only a restricted number of array board patterns are disposed on a working panel. Therefore, a region of the working panel, which remains unused after the array board patterns are disposed thereon, may be a loss region which is a region which is not being utilized.

### SUMMARY

The present inventive concepts provide a working panel, which may increase the yield of unit board patterns per unit working panel by arranging patterns in the loss region of the working panel, and a working panel set.

The above and other objects of the present inventive concept will be described in or be apparent from the following description of the example embodiments of the inventive concepts.

According to an aspect of the present inventive concepts, there is provided a working panel including first array board patterns arranged in a first region and including first and second guide bar patterns spaced apart from each other and N first unit board patterns, where N is a natural number greater than or equal to 2, positioned between the first and second guide bar patterns, and second array board patterns including third and fourth guide bar patterns spaced apart from each other, and M second unit board patterns, where 1≦M<N, positioned between the third and fourth guide bar patterns.

In one embodiment, the N first unit board patterns are consecutively arranged in a lengthwise direction of the first guide bar patterns, and the M second unit board patterns are consecutively arranged in a lengthwise direction of the third guide bar pattern.

In another embodiment, opposite ends of the N first unit board patterns are connected to the first and second guide bar patterns, and opposite ends of the M second unit board patterns are connected to the third and fourth guide bar patterns, respectively.

In another embodiment, neighboring ones of the N first unit board patterns are arranged to be spaced apart from each other, and neighboring ones of the M second unit board patterns are arranged to be spaced apart from each other.

In one embodiment, the first unit board patterns and the second unit board patterns have the same patterns.

In one embodiment, the first and second guide bar patterns are longer than the third and fourth guide bar patterns.

In one embodiment, an interval between the first and second guide bar patterns is the same as an interval between the third and fourth guide bar patterns.

In one embodiment, a plurality of the first array board patterns are arranged in the first region, and one or more of the second array board patterns are arranged in the second region.

In one embodiment, a third array board pattern is further arranged in the second region, and the third array board pattern includes fifth and sixth guide bar patterns facing each other and less than N third unit board patterns positioned between the fifth and sixth guide bar patterns.

In one embodiment, N is the number of unit boards included in a unit array board provided in a surface mounting technology (SMT) process.

According to another aspect of the present inventive concepts, there is provided a working panel set including first to Lth working panels, where L is a natural number greater than or equal to 2, wherein the kth one of the working panels, where 1≦k≦L, includes first array board patterns including a first guide bar pattern and N first unit board patterns consecutively arranged in the lengthwise direction of the first guide bar pattern, where N is a natural number greater than or equal to 2, and second array board patterns including a second guide bar pattern and M(k) second unit board patterns, where 1≦M(k)<N, consecutively arranged in the lengthwise direction of the second guide bar pattern, and

$${\sum }_{k = 1}^{L} M ( k ) = N .$$

In one embodiment, one end of each of the N first unit board patterns is connected to the first guide bar pattern, and one end of each of the M second unit board patterns is connected to the second guide bar pattern.

In one embodiment, neighboring ones of the N first unit board patterns are arranged to be spaced apart from each other, and neighboring ones of the M(k) second unit board patterns are arranged to be spaced apart from each other.

In one embodiment, the first guide bar pattern is longer than the second guide bar pattern.

In one embodiment, N is the number of unit boards included in a unit array board provided in a surface mounting technology (SMT) process.

According to another aspect of the present inventive concepts, there is provided a working panel which includes a first region, a second region and a plurality of first array board patterns in the first region. Each of the first array board patterns has a first guide bar pattern and N first unit board patterns, where N is a natural number greater than or equal to 2, connected to the first guide bar pattern. The working panel further includes a plurality of second array board patterns in the second region. Each of the plurality of second array board patterns has a second guide bar pattern and M second unit board patterns, where 1≦M<N, connected to the second guide bar pattern.

In one embodiment, the N first unit board patterns are consecutively arranged in a lengthwise direction of the first guide bar patterns, and the M second unit board patterns are consecutively arranged in a lengthwise direction of the second guide bar pattern.

In another embodiment, each of the plurality of first array board patterns comprises a third guide bar pattern and each of the plurality of second array board patterns comprises a fourth guide bar pattern.

In another embodiment, opposite ends of the N first unit board patterns are connected to the first and fourth guide bar patterns, and opposite ends of the M second unit board patterns are connected to the second and fourth guide bar patterns, respectively.

In another embodiment, neighboring ones of the N first unit board patterns are arranged to be spaced apart from each other, and neighboring ones of the M second unit board patterns are arranged to be spaced apart from each other.

### BRIEF DESCRIPTION OF THE DRAWINGS

The foregoing and other features and advantages of the inventive concepts will be apparent from the more particular description of preferred aspects of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings, the thickness of layers and regions are exaggerated for clarity.

FIG. 1 is a schematic plan view of a working panel in accordance with an example embodiment of the present inventive concepts.

FIG. 2 is a schematic plan view of a first array board in accordance with an example embodiment of the present inventive concepts.

FIG. 3 is a schematic plan view of a second array board in accordance with an example embodiment of the present inventive concepts.

FIG. 4 is a schematic plan view illustrating connections between array boards in the working panel illustrated in FIG. 1.

FIG. 5 is a schematic plan view of a working panel in accordance with an example embodiment of the present inventive concepts.

FIG. 6 is a schematic plan view of a working panel in accordance with an example embodiment of the present inventive concepts.

FIG. 7 is a schematic plan view of a working panel in accordance with an example embodiment of the present inventive concepts.

FIG. 8A is a schematic plan view of a working panel in accordance with an example embodiment of the present inventive concepts. FIG. 8B is a detailed view of section A of FIG. 8A in accordance with an example embodiment of the inventive concepts. 8C is a detailed view of section B of FIG. 8A in accordance with an example embodiment of the inventive concepts.

FIG. 9 is a schematic plan view illustrating connections between array boards in the working panel illustrated in FIGS. 8A-C;

FIG. 10A is a schematic plan view of a working panel in accordance with an example embodiment of the present inventive concepts. FIG. 10B is a detailed view of section C of FIG. 10A in accordance with an example embodiment of the inventive concepts. 10C is a detailed view of section D of FIG. 10A in accordance with an example embodiment of the inventive concepts.

FIG. 11 is a schematic plan view illustrating connections between array boards in the working panel illustrated in FIGS. 10A-C.

FIG. 12 is a schematic plan view of a working panel in accordance with an example embodiment of the present inventive concepts.

FIG. 13 is a schematic plan view of a working panel set in accordance with an example embodiment of the present inventive concepts.

FIG. 14 is a schematic plan view illustrating connections between array boards in the working panel set illustrated in FIG. 13.

### DETAILED DESCRIPTION OF THE EMBODIMENTS

Various exemplary embodiments will be described more fully hereinafter with reference to the accompanying drawings, in which some example embodiments are shown. The present inventive concepts may, however, be embodied in many different forms and should not be construed as limited to the exemplary embodiments set forth herein. The present inventive concepts may, however, be embodied in many different forms and should not be construed as limited to the example embodiments set forth herein. It will be understood that when an element or layer is referred to as being “on,” “connected to,” or “coupled to” another element or layer, it can be directly on, connected to or coupled to another element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, for example, a first element, component, region, layer or section discussed below could be termed a second element, component, region layer or section without departing from the teachings of the present inventive concepts.

The terminology used herein is for the purpose of describing particular example embodiments only and is not intended to be limiting of the inventive concepts. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Exemplary embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present inventive concepts.

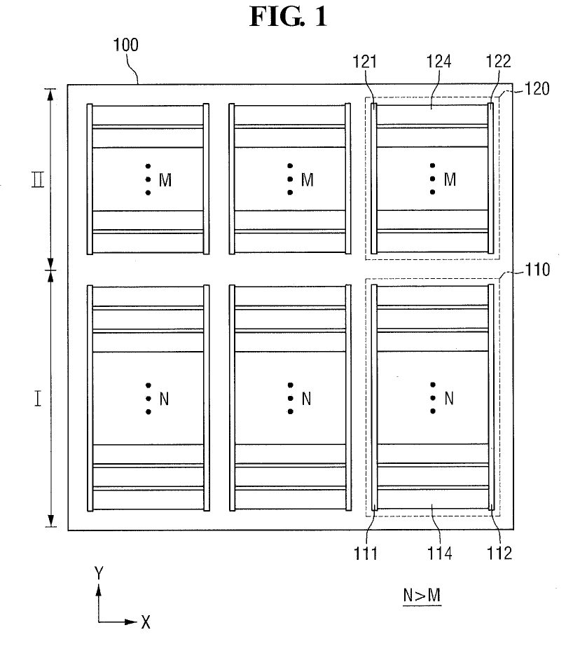

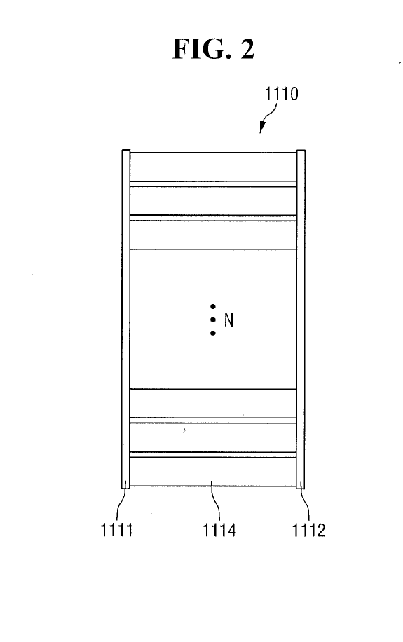

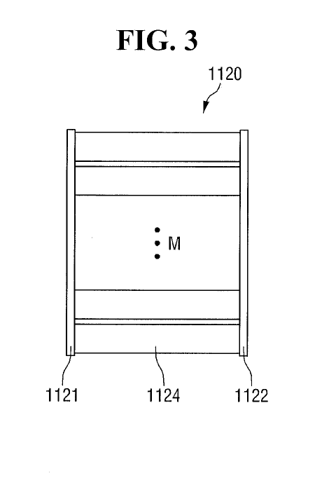

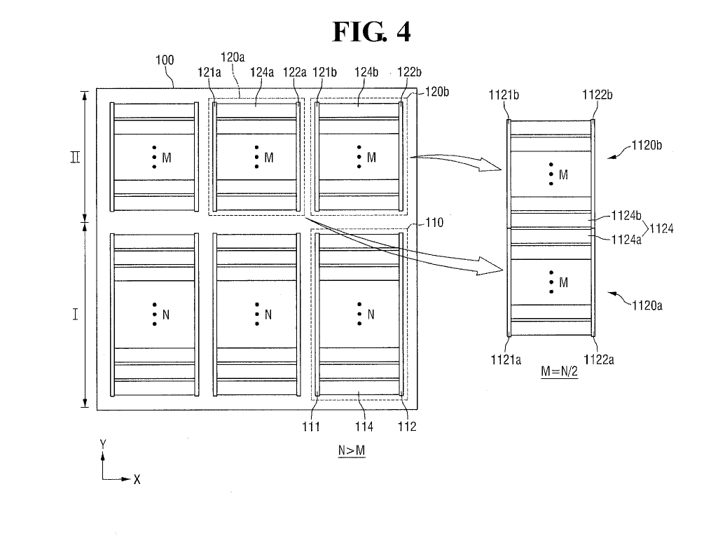

Hereinafter, a working panel in accordance with an example embodiment of the present inventive concepts will be described with reference to FIGS. 1 to 4. FIG. 1 is a schematic plan view of a working panel in accordance with an example embodiment of the present inventive concepts, FIG. 2 is a schematic plan view of a first array board, FIG. 3 is a schematic plan view of a second array board, and FIG. 4 is a schematic plan view illustrating connections between array boards in the working panel illustrated in FIG. 1.

Referring to FIG. 1, a working panel 100 in accordance with the example embodiment of the present inventive concepts includes first array board patterns 110 arranged in a first region I and second array board patterns 120 arranged in a second region II different from the first region I. The first array board patterns 110 each include a first guide bar pattern 111 and a second guide bar pattern 112 facing each other, and N first unit board patterns 114 (N is a natural number greater than or equal to 2.) positioned between the first and second guide bar patterns 111 and 112. The first and second guide bar patterns 111 and 112 are spaced apart from each other. The second array board patterns 120 each include a third guide bar pattern 121 and a fourth guide bar pattern 122 facing each other, and M second unit board patterns 124 (1≦M<N) positioned between the third and fourth guide bar patterns 121 and 122. The third and fourth guide bar patterns 121 and 122 are spaced apart from each other. The second array board patterns 120 have fewer unit board patterns than the first array board patterns.

The working panel 100 may be, for example, a printed circuit board (PCB) panel, but is not limited thereto. For example, PCB shaped patterns may be formed on the working panel 100. When the working panel 100 is processed according to the PCB pattern, a single type PCB board product, for example, may be produced.

The working panel 100 may include the first region I and the second region II. The first region I may be defined as a region of the working panel 100 in which the first array board patterns 110 are arranged. The second region II may be defined as a region of the working panel 100 excluding the first region I. That is, second region II may be defined as a region in which the first array board patterns are not arranged.

The first and second guide bar patterns 111 and 112 may have the same patterns as each other, but the present inventive concept is not limited thereto.

The first unit board patterns 114 may be patterns shaped of a single type PCB board product. However, the inventive concept does not limit the shapes of the first unit board patterns 114 to rectangular patterns and the first unit board patterns 114 may have other various shapes. The N first unit board patterns 114 may be consecutively arranged in the lengthwise direction of the first guide bar pattern 111, that is, in the Y-direction. In addition, neighboring ones of the first unit board patterns 114 may be arranged to be spaced apart from each other in the lengthwise direction of the first guide bar pattern 111. Opposite ends of each of the first unit board patterns 114 may be connected to the first and second guide bar patterns 111 and 112, respectively. Neighboring ones of the first array board patterns 110 may be spaced apart in the widthwise direction of the first guide bar pattern 111, that is, the X-direction.

As described above, first array board patterns 110 are arranged in the first region I of the working panel 100, the N first unit board patterns 114 in the first array board patterns 110 are connected to the first and second guide bar patterns 111 and 112 positioned at opposite sides of the first unit board patterns 114. Therefore, referring to FIG. 2, the working panel 100 is patternwise fabricated, thereby producing a first array board 1110 in which N first unit boards 1114 are connected to first and second guide bars 1111 and 1112 positioned at opposite sides of the N first unit boards 1114.

After producing the first array board 1110, an SMT process may be performed to mount electronic components on the first array board 1110. In order to increase the efficiency of the SMT process, the SMT process may be performed on an array board including a plurality of unit boards used as a basic unit board. For example, the first array board 1110 may be used as the basic unit board, which may be defined as including N consecutively arranged unit boards. Therefore, the SMT process is performed on the N consecutively arranged first unit boards 1114 forming one single first array board 1110 using the first array board 1110 as the basic unit board.

However, if the first array board 1110 including the N consecutively arranged first unit boards 1114 is determined as the basic unit board, the SMT process cannot be performed on an array board including fewer than or more than N consecutively arranged unit boards.

Referring back to FIG. 1, the second array board patterns 120 are arranged in the second region II. The second array board patterns 120 include third and fourth guide bar patterns 121 and 122 facing each other, and M second unit board patterns 124 positioned between the third and fourth guide bar patterns 121 and 122. The number (M) of the second unit board patterns 124 included in the second array board patterns 120 is smaller than the number (N) of the first unit board patterns 114 included in the first array board patterns 110, that is, M<N. In other words, each of the second array board patterns 120 includes fewer unit board patterns than the N unit boards included in the basic unit board.

The third and fourth guide bar patterns 121 and 122 may have the same patterns, but the present inventive concept is not limited thereto.

The second unit board patterns 124 may have patterns shaped of a single type PCB board product. However, the inventive concept does not limit the shapes of the second unit board patterns 124 to rectangular patterns. The second unit board patterns 124 may have various shapes. The M second unit board patterns 124 may be consecutively arranged in the lengthwise direction of the third guide bar pattern 121, that is, the Y-direction. In addition, neighboring ones of the second unit board patterns 124 may be arranged to be spaced apart from each other in the lengthwise direction of the third guide bar pattern 121. Opposite ends of the first unit board patterns 114 may be connected to the first and second guide bar patterns 111 and 112, respectively. Neighboring ones of the second array board patterns 120 may be spaced apart in the widthwise direction of the second guide bar pattern 121, that is, the X-direction.

Referring to FIG. 1, the first array board patterns 110 and the second array board patterns 120 are described by comparison thereof.

The first unit board patterns 114 included in the first array board patterns 110 and the second unit board patterns 124 included in the second array board patterns 120 may have the same patterns. In addition, since unit board patterns are positioned between guide bar patterns, an interval between the first and second guide bar patterns 111 and 112 may be the same as an interval between the third and fourth guide bar patterns 121 and 122. That is to say, a width of the first array board pattern 110 may be equal to a width of the second array board pattern 120.

The number (M) of the second unit board patterns 124 included in the second array board patterns 120 is smaller than the number (N) of the first unit board patterns 114 included in the first array board patterns 110, that is, M<N. The first and second guide bar patterns 111 and 112 are connected to the N first unit board patterns 114, and the third and fourth guide bar patterns 121 and 122 are connected to the M second unit board patterns 124 (M<N). Thus, the first and second guide bar patterns 111 and 112 may be longer than the third and fourth guide bar patterns 121 and 122.

Next, the working panel in accordance with an example embodiment of the present inventive concept will be described in detail.

Referring to FIG. 1, the first array board patterns 110 may be arranged in the first region I of the working panel 100. As described above, the basic unit board provided in the SMT process may be defined as including consecutively arranged N unit boards. Therefore, in order to efficiently utilize the working panel 100, as many first array board patterns 110 as possible may be arranged on the working panel 100.

As described above, the second region II may be defined as a region of the working panel 100, excluding the first region I. Since the second region II is the region of the working panel 100 remaining after arranging as many first array board patterns 110 as possible on the working panel 100, it may be insufficient to arrange the first array board patterns 110 on the working panel 100. That is, unused space may remain on the working panel 100 after the first array board patterns 110 are arranged on the working panel 100. Since the second array board patterns 120 include fewer unit board patterns than the first array board patterns 110, they occupy a smaller space than the first array board patterns 110. Therefore, the second array board patterns 120 may be arranged in the second region II. For example, one or more of the second array board patterns 120 may be arranged in the second region II.

In the working panel 100 according to the example embodiment of the present inventive concepts, since the second array board patterns 120 are arranged in the second region II, the space of the working panel 100 can be efficiently utilized. That is to say, as many array board patterns as possible may be arranged on the working panel 100 using a restricted size of the working panel 100. In addition, since the number of array board patterns arranged on the working panel 100 increases, the number of unit boards produced by the working panel 100 may also increase.

The number (M) of unit board patterns included in the second array board patterns 120 is smaller than the number (N) of unit boards included in the basic unit board provided for the SMT process. Therefore, referring to FIGS. 3 and 4, a second array board 1120 may be fabricated such that the basic unit board includes N unit boards. Then, the SMT process may be performed using the fabricated basic unit board.

As illustrated in FIG. 3, the working panel 100 is patternwise fabricated, thereby producing a second array board 1120 in which M second unit boards 1124 are connected to third and fourth guide bars 1121 and 1122 positioned at opposite sides of the M second unit boards 1124.

As illustrated in FIG. 4, one or more second array board patterns 120a and 120b are arranged in the second region II. The one or more second array board patterns 120a and 120b include third guide bar patterns 121a and 121b, respectively, fourth guide bar patterns 122a and 122b, respectively, facing each other, and M second unit board patterns 124a and 12b, respectively, positioned between the third and fourth guide bar patterns 121a, 121b and 122a and 122b, respectively. A plurality of second array boards 1120a and 1120b may be produced by fabricating the working panel 100. For example, when M=N/2, the second array board 1120a including M second unit boards 1124a and the second array board 1120b including M second unit boards 1124b are combined to produce a basic unit board including N second unit boards 1124. In order to combine the second array boards 1120a and 1120b with each other, third and fourth guide bars 1121a and 1122a of the second array board 1120a may be combined with third and fourth guide bars 1121b and 1122b of the second array board 1120b, respectively.

As described above, the second array board 1120 may be fabricated such that the basic unit board includes N unit boards. Then, the SMT process may be performed using the fabricated basic unit board. Therefore, since the second region II of the working panel 100 may be utilized by the working panel 100 according to the example embodiment of the present inventive concepts, as many basic unit boards as possible may be produced using a restricted space of the working panel 100.

However, the inventive concepts are not limited in scope to the second array boards 1120 being fabricated according to the shapes of the second array board patterns 120 to produce basic unit boards, and it is evident to one skilled in the art that the second array boards 1120 may be utilized in various manners.

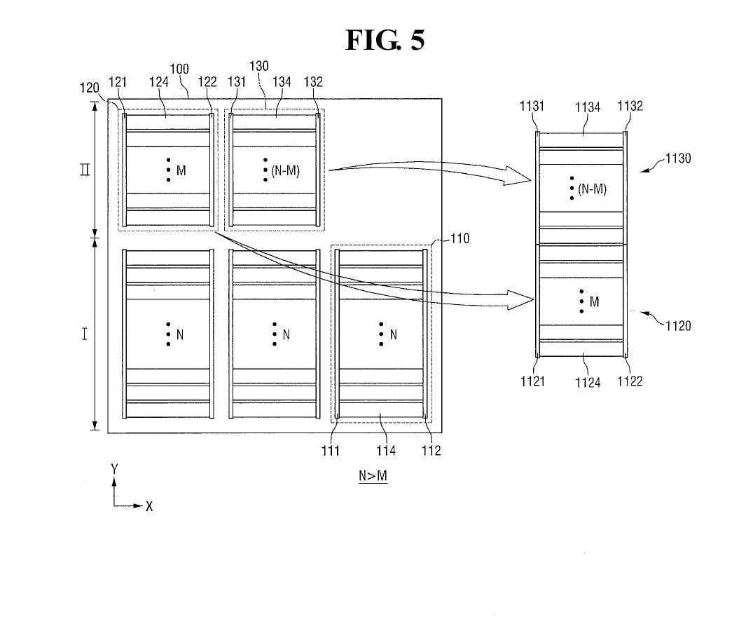

A working panel in accordance with an example embodiment of the present inventive concepts will now be described with reference to FIG. 5. The following description will focus on differences between the working panels according to the previous and present embodiments. FIG. 5 is a schematic plan view of a working panel in accordance with an example embodiment of the present inventive concepts.

In the working panel 100 according to the example embodiment of the present inventive concept, a third array board pattern 130 may further be arranged in a second region II. The third array board pattern 130 may include fifth and sixth guide bar patterns 131 and 132 facing each other and less than N third unit board patterns 134 positioned between the fifth and sixth guide bar patterns 131 and 132. In FIG. 5, the number of third unit board patterns 134 is N−M.

The third unit board patterns 134 may be the same patterns as the first and second unit board patterns 114 and 124. While the number of third unit board patterns 134 is set to N−M in FIG. 5, the inventive concepts do not limit the number of third unit board patterns 134 to N−M, as long as the number of third unit board patterns 134 is not greater than N.

Since the third array board pattern 130 includes fewer unit board patterns than the first array board patterns 110, they occupy a smaller space than the first array board patterns 110. Therefore, the third array board pattern 130 may be arranged in the second region II.

Next, a method of producing a basic unit board using a third array board 1130 will be described. The second array board 1120 and third array board 1130 may be produced by fabricating the working panel 100 of FIG. 5. The second array board 1120 including M second unit boards 1124, and the third array board 1130 including (N−M) third unit boards 1134, are combined to produce a basic unit board including N unit boards. In order to combine the second array boards 1120 and the third array board 1130 with each other, third and fourth guide bars 1121 and 1122 may be combined with fifth and sixth guide bars 1131 and 1132, respectively.

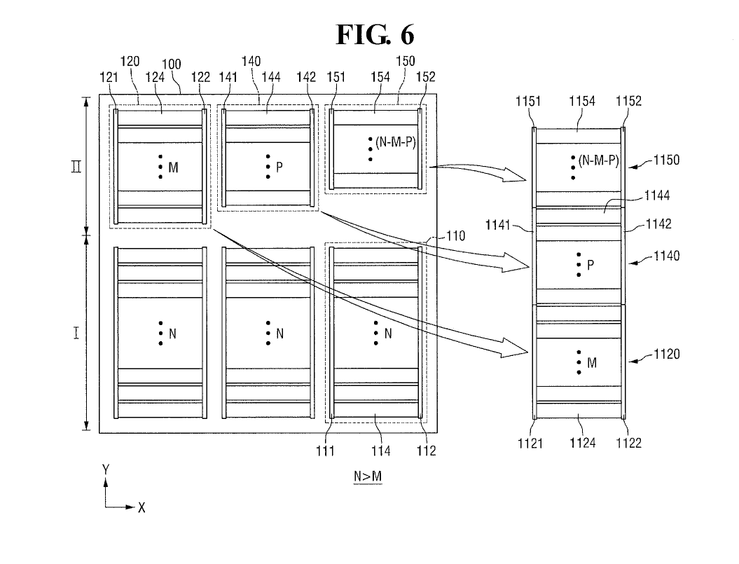

A working panel in accordance with an example embodiment of the present inventive concepts will now be described with reference to FIG. 6. However, the following description will focus on differences between the working panels according to the previous and present embodiments. FIG. 6 is a schematic plan view of a working panel in accordance with an example embodiment of the present inventive concepts.

In the working panel 100 according to the example embodiment of the present inventive concepts, fourth and fifth array board patterns 140 and 150 may further be arranged in a second region II. The fourth array board pattern 140 may include seventh and eighth guide bar patterns 141 and 142 facing each other and less than N fourth unit board patterns 144 positioned between the seventh and eighth guide bar patterns 141 and 142. In addition, the fifth array board pattern 150 may include ninth and tenth guide bar patterns 151 and 152 facing each other and less than N fifth unit board patterns 154 positioned between the ninth and tenth guide bar patterns 151 and 152. The fourth array board patterns 140 include P unit board patterns 144, where 0<P<N. The fifth array board patterns 150 include N−M−P unit board patterns.

The fourth and fifth unit board patterns 144 and 154 may have the same patterns as the first and second unit board patterns 114 and 124. While the number of fourth unit board patterns 144 is set to P (0<P<N) and the number of fifth unit board patterns 154 is set to N−M−P in FIG. 6, the inventive concepts do not limit the numbers of fourth and fifth unit board patterns 144 and 154 thereto as long as the numbers of fourth and fifth unit board patterns 144 and 154 are not greater than N.

Since the fourth and fifth array board patterns 140 and 150 include fewer unit board patterns than the first array board patterns 110, they occupy a smaller space than the first array board patterns 110. Therefore, the fourth and fifth array board patterns 140 and 150 may be arranged in the second region II.

Next, a method of producing a basic unit board using the fourth and fifth array boards 1140 and 1150 will be described. The second, fourth and fifth array boards 1120, 1140 and 1150 may be produced by fabricating the working panel 100. The second array board 1120 including M second unit boards 1124, the fourth array board 1140 including P fourth unit boards 1144, and the fifth array board 1150 including (N−M−P) fifth unit boards 1154 are combined to produce a basic unit board including N unit boards. In order to combine the second, fourth and fifth array boards 1120, 1140 and 1150 with one another, guide bars 1121, 1122, 1141, 1142, 1151 and 1152 of the second, fourth and fifth array boards 1120, 1140 and 1150, respectively, may be combined with one another. Specifically, the seventh guide bars 1141 are combined with the second guide bars 1121 and the ninth guide bars 1151 and the eighth guide bars 1142 are combined with the third guide bars 1122 and the tenth guide bars 1152.

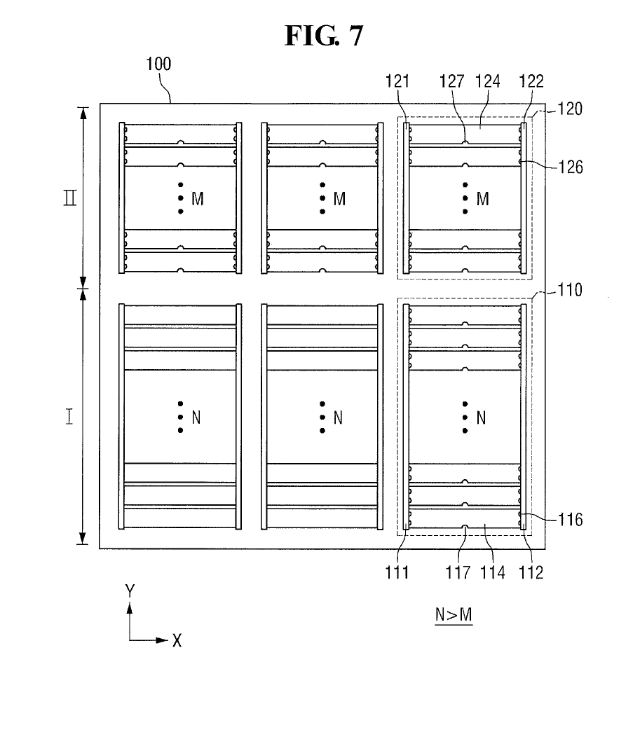

A working panel in accordance with an example embodiment of the present inventive concepts will now be described with reference to FIG. 7. The following description will focus on differences between the working panels according to the previous and present embodiments. FIG. 7 is a schematic plan view of a working panel in accordance with an example embodiment of the present inventive concepts.

In the working panel 100 of FIG. 7 according to the example embodiment of the present inventive concepts, first unit board patterns 114 and second unit board patterns 124 may include first side hole patterns 116 and second side hole patterns 116 at opposite ends thereof The first and second side hole patterns 116 and 126 may be removed when the working panel 100 is fabricated. If the regions where the first and second side hole patterns 116 and 126 are disposed are removed when the working panel 100 is fabricated, contact areas between guide bars and unit boards may be reduced. Therefore, after performing an SMT process, an array board (not shown) may be easily separated into unit boards (not shown).

In addition, the first unit board patterns 114 and the second unit board patterns 124 may include first guide groove patterns 117 and second guide groove patterns 127, respectively. The first and second guide groove patterns 117 and 127 may be disposed at corners of the first and second unit board patterns 114 and 124, respectively, where the first and second side hole patterns 116 and 126 are not formed. The first and second guide groove patterns 117 and 127 may be removed when the working panel 100 is fabricated. If first and second unit boards (not shown) are connected to an electronic device, guide grooves (not shown) may be used as alignment marks for determining a direction in which the first and second unit boards (not shown) are connected.

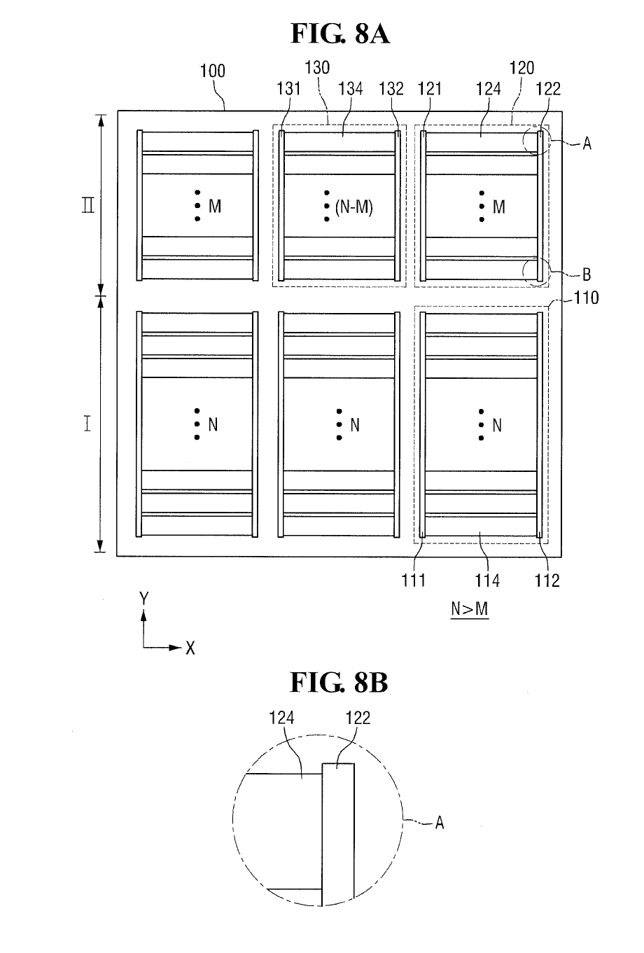

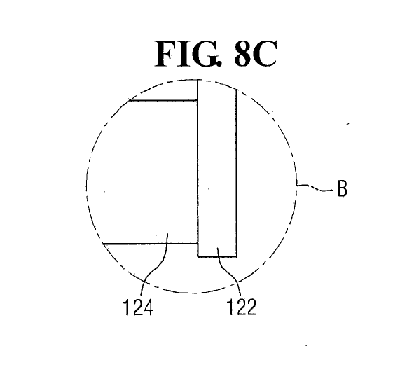

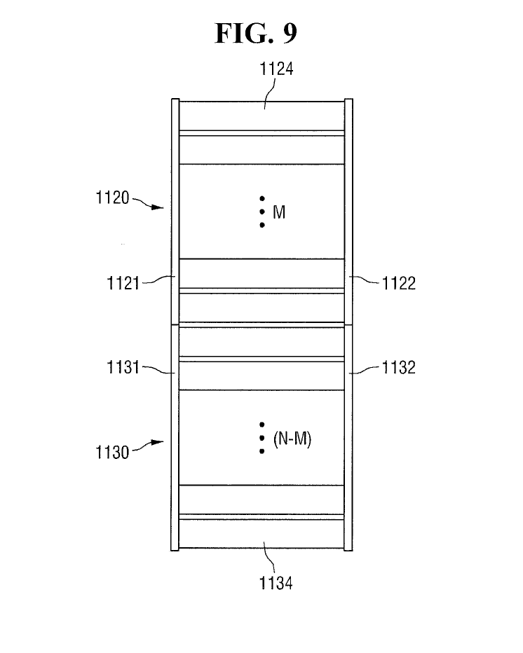

A working panel in accordance with an example embodiment of the present inventive concepts will now be described with reference to FIGS. 8A-C and 9. However, the following description will focus on differences between the working panels according to the previous and present embodiments. FIG. 8A is a schematic plan view of a working panel in accordance with an example embodiment of the present inventive concepts, FIG. 8B is a detailed view of section A of FIG. 8A, 8C is a detailed view of section B of FIG. 8A, and FIG. 9 is a plan view illustrating connection between array boards in the working panel illustrated in FIGS. 8A-8C.

In FIGS. 8A, 8B and 8C, in the working panel 100 in accordance with the example embodiment of the present inventive concepts, both ends of the third and fourth guide bar patterns 121 and 122 may outwardly protrude relative to the second unit board patterns 124. However, the inventive concepts are not limited thereto. In one example embodiment, only one end of the third or fourth guide bar pattern 121, 122 may outwardly protrude relative to the second unit board patterns 124.

If the ends of the third and fourth guide bar patterns 121 and 122 outwardly protrude relative to the second unit board patterns 124, the basic unit board may be easily produced using the second array board 1120.

Referring to FIG. 9, since the ends of the third and fourth guide bars 1121 and 1122 of the second array board 1120 protrude, the second unit boards 1124 and the third unit boards 1134 may be spaced apart from each other without contacting each other in a case where the third and fourth guide bars 1121 and 1122 of the second array board 1120 contact the fifth and sixth guide bars 1131 and 1132 of the third array board 1130.

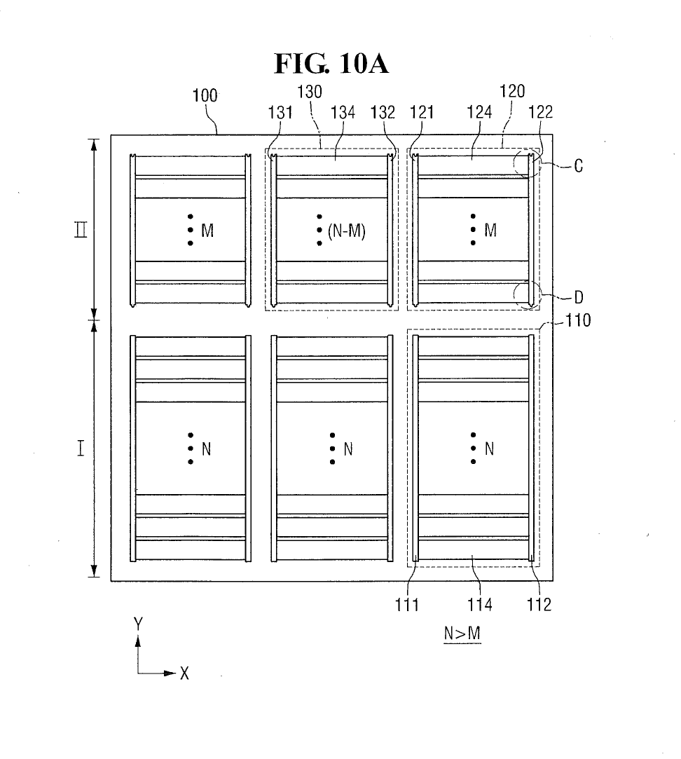

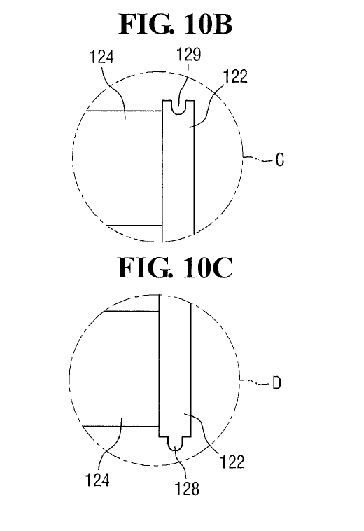

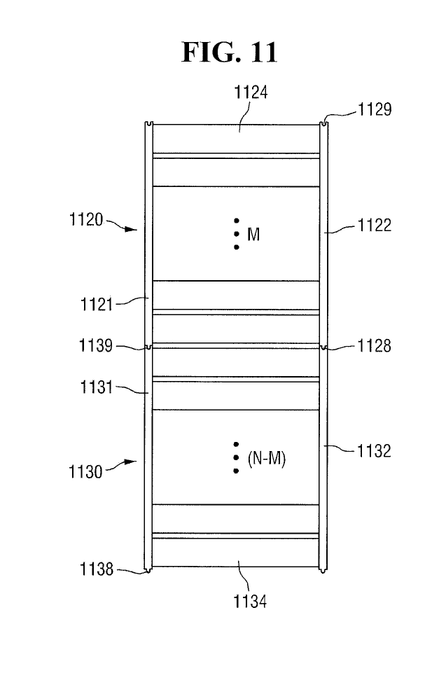

A working panel in accordance with an example embodiment of the present inventive concepts will now be described with reference to FIGS. 10A-C and 11. However, the following description will focus on differences between the working panels according to the previous and present embodiments. FIG. 10A is a schematic plan view of a working panel in accordance with an example embodiment of the present inventive concepts, FIG. 10B is a detailed view of section C of FIG. 10A, 10C is a detailed view of section D of FIG. 10A and FIG. 11 is a schematic plan view illustrating connections between array boards in the working panel illustrated in FIGS. 10A-10C.

In the working panel 100 of FIGS. 10A, 10B and 10C in accordance with the example embodiment of the present inventive concepts, first connector patterns 128 may be formed at one end of each of third and fourth guide bar patterns 121 and 122 and second connector patterns 129 may be formed at the other ends of the third and fourth guide bar patterns 121 and 122. However, the inventive concepts are not limited thereto. In one example embodiment, only the first connector patterns 128 may be formed at one end of the third and fourth guide bar patterns 121 and 122. Alternatively, only the second connector patterns 129 may be formed only at one end of the third and fourth guide bar patterns 121 and 122. Alternatively, the first connector patterns 128 may be formed only at one end of either the third guide bar pattern 121 or the fourth guide bar pattern 122. Alternatively, the second connector patterns 129 may be formed only at one end of either the third guide bar pattern 121 or the fourth guide bar pattern 122.

The first connector patterns 128 and the second connector patterns 129 may be defined as patterns that may be mated with each other. For example, the first connector patterns 128 may be convex patterns and the second connector patterns 129 may be concave patterns. However, the present inventive concepts do not limit the shape of the pattern thereto, as long as the first connector patterns 128 and the second connector patterns 129 may be mated with each other.

In addition, in FIG. 10A, first connector patterns may be formed at one end of the fifth and sixth guide bar patterns 131 and 132 and second connector patterns may be formed at the other ends of the fifth and sixth guide bar patterns 131 and 132.

If the first connector patterns 128 or the second connector patterns 129 are formed at the ends of the third and fourth guide bar patterns 121 and 122, the basic unit board may be easily produced using the second array board 1120 formed by fabricating the working panel 100. If a first connector 1128 of the third and fourth guide bars 1121 and 1122 of the second array board 1120 is mated with a second connector 1139 of fifth and sixth guide bars 1131 and 1132 of the third array board 1130, a contact area between guide bars increases, thereby increasing a connection force between the second and third array boards 1120 and 1130. The third and fourth guide bars 1121 and 1122 of the second array board 1120 include second connectors 1129 and the fifth and sixth guide bars 1131 and 1132 of the third array board 1130 include first connectors 1138.

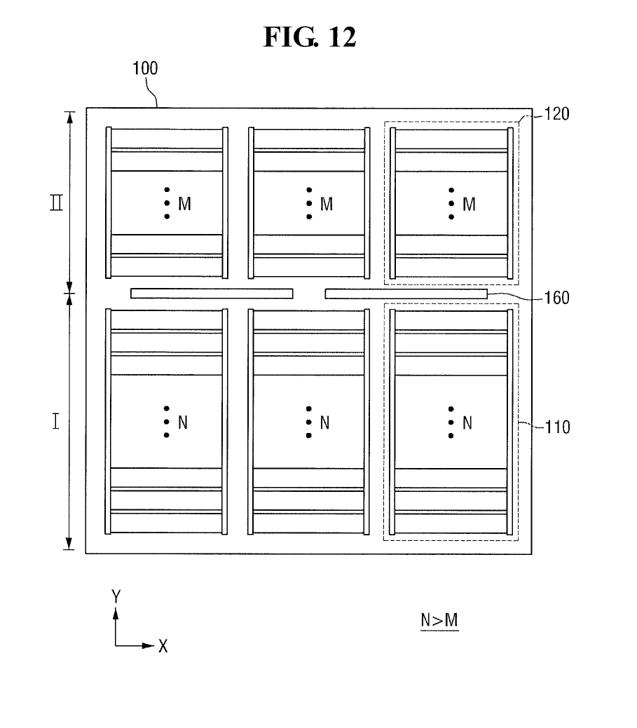

A working panel in accordance with an example embodiment of the present inventive concepts will now be described with reference to FIG. 12. However, the following description will focus on differences between the working panels according to the previous and present embodiments. FIG. 12 is a schematic plan view of a working panel in accordance with an example embodiment of the present inventive concepts.

In the working panel 100 of FIG. 12 according to the example embodiment of the present inventive concepts, impedance coupon patterns 160 may further be disposed on the working panel 100. For example, when unit boards are used in producing a memory device, the impedance coupon patterns 160 may be disposed on the working panel 100. The impedance coupon patterns 160 may be formed on regions of the working panel 100, where first and second array board patterns 110 and 120 are not disposed. Impedance of first and second unit boards (not shown) may be measured using regions where the impedance coupon patterns 160 are disposed.

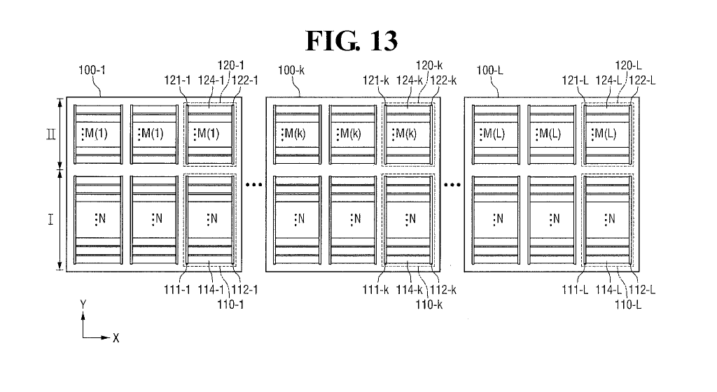

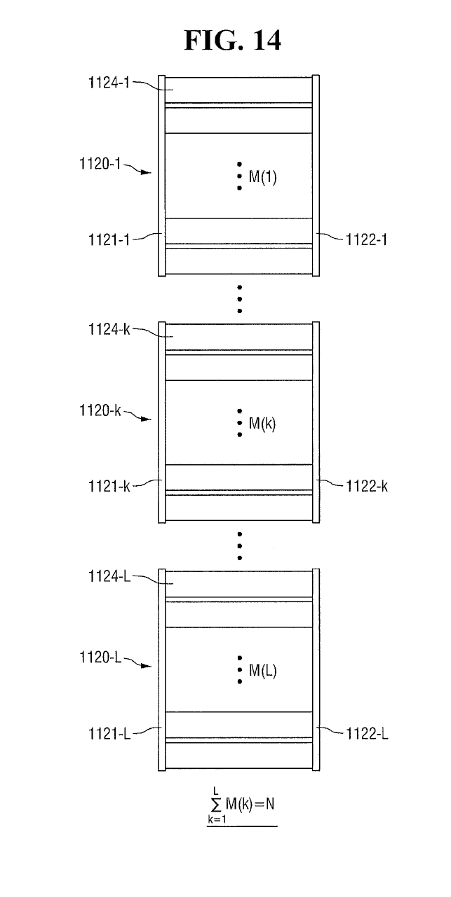

A working panel set according to an example embodiment of the present inventive concepts will now be described with reference to FIGS. 13 and 14. However, the following description will focus on differences between the working panels according to the previous and present embodiments. The aforementioned working panels according to various example embodiments of the present inventive concepts may also be applied to the working panel set according to the example embodiment of the present inventive concepts. FIG. 13 is a schematic plan view of a working panel set in accordance with an example embodiment of the present inventive concepts, and FIG. 14 is a schematic plan view illustrating connections between array boards in the working panel set illustrated in FIG. 13.

In FIG. 13, the working panel set according to the example embodiment of the present inventive concepts includes first to Lth working panels 100-1 to 100-L (L is a natural number greater than or equal to 2). The first working panel 100-1 may have a first region I and a second region II. The first region I may be defined as a region of the first working panel 100-1, where the first array board patterns 110-1 are disposed. The second region II may be defined as a region of the first working panel 100-1, excluding the first region I.

In detail, each of the first array board patterns 110-1 includes first and second guide bar patterns 111-1 and 112-1 facing each other, and N first unit board patterns 114-1, where N is a natural number greater than or equal to 2, positioned between the first and second guide bar patterns 111-1 and 112-1.

Each of the second array board patterns 120-1 includes third and fourth guide bar patterns 121-1 and 122-1 facing each other, and M(1) second unit board patterns 124-1, where 1≦M(1)<N, positioned between the third and fourth guide bar patterns 121-1 and 122-1. Since the second array board patterns 120-1 includes fewer unit board patterns than the first array board patterns 110-1, they occupy a smaller space than the first array board patterns 110-1. Therefore, the second array board patterns 120-1 may be arranged in the second region II.

The Lth working panel 100-L may have a first region I and a second region II. The first region I may be defined as a region of the Lth working panel 100-L, where the first array board patterns 110-L are disposed. The second region II may be defined as a region of the Lth working panel 100-L, excluding the first region I.

In detail, each of the first array board patterns 110-L includes first and second guide bar patterns 111-L and 112-L facing each other, and N first unit board patterns 114-L, where N is a natural number greater than or equal to 2, positioned between the first and second guide bar patterns 111-L and 112-L.

Each of the second array board patterns 120-L includes third and fourth guide bar patterns 121-L and 122-L facing each other, and M(L) second unit board patterns 124-L, where 1≦M(L)<N, positioned between the third and fourth guide bar patterns 121-L and 122-L. Since the second array board patterns 120-L includes fewer unit board patterns than the first array board patterns 110-L, they occupy a smaller space than the first array board patterns 110-L. Therefore, the second array board patterns 120-L may be arranged in the second region II.

Here, the kth one of the working panels 100-k, where 1≦k≦L, includes a first array board pattern 110-k and a second array board pattern 120-k. The first array board pattern 110-k includes a first guide bar pattern 111-k, a second guide bar pattern 112-k and N first unit board patterns 114-k consecutively arranged in the lengthwise direction of the first guide bar pattern 111-k, where N is a natural number greater than or equal to 2. The second array board pattern 120-k includes a third guide bar pattern 121-k, a fourth guide bar pattern 122-k and M(k) second unit board patterns 124-k, where 1≦M(k)<N, consecutively arranged in the lengthwise direction of the third guide bar pattern 121-k, and

$${\sum }_{k = 1}^{L} M ( k ) = N .$$

The kth working panel 100-k may have a first region I and a second region II. The first region I may be defined as a region of the kth working panel 100-k, where the first array board patterns 110-k are disposed. The second region II may be defined as a region of the kth working panel 100-k, excluding the first region I.

In detail, each of the first array board patterns 110-k includes first and second guide bar patterns 111-k and 112-k facing each other, and N first unit board patterns 114-k, where N is a natural number greater than or equal to 2, positioned between the first and second guide bar patterns 111-k and 112-k.

Each of the second array board patterns 120-k includes third and fourth guide bar patterns 121-k and 122-k facing each other, and M(k) second unit board patterns 124-k, where 1≦M(k)<N, positioned between the third and fourth guide bar patterns 121-k and 122-k. Since the second array board patterns 120-k includes fewer unit board patterns than the first array board patterns 110-k, they occupy a smaller space than the first array board patterns 110-k. Therefore, the second array board patterns 120-k may be arranged in the second region II.

Next, a method of producing a basic unit board using a second array board 1120-k will be described. The second array board 1120-k including M(k) second unit boards 1124-k may be produced by fabricating the kth working panel 100-k. In the same manner, L second array boards 1120-1 to 1120-L including M(1) to M(L) second unit boards 1124-1 to 1124-L may be produced by fabricating the first to Lth working panels 100-1 to 100-L. Next, referring to FIG. 14, the L second array boards 1120-1 to 1120-L may be combined with each other by fabricating the first to Lth working panels 100-1 to 100-L. Since the L second array boards 1120-1 to 1120-L include M(1) to M(L) second unit boards 1124-1 to 1124-L and

$${\sum }_{k = 1}^{L} M ( k ) = N ,$$

the basic unit board including N unit boards may be produced by combining the L second array boards 1120-1 to 1120-L. In order to combine the L second array boards 1120-1 to 1120-L to each other, the respective guide bars 1121-1, 1122-1, 1121-k, 1122-k, 1121-L and 1122-L may be combined with each other.

While the present inventive concepts have been particularly shown and described with reference to example embodiments thereof, it will be understood by those of ordinary skill in the art that various changes in form and details may be made therein without departing from the spirit and scope of the present inventive concepts as defined by the following claims. It is therefore desired that the present example embodiments be considered in all respects as illustrative and not restrictive, reference being made to the appended claims rather than the foregoing description to indicate the scope of the inventive concepts.

What is claimed is:

1. A working panel comprising:
first array board patterns arranged in a first region and including first and second guide bar patterns spaced apart from each other and N first unit board patterns, where N is a natural number greater than or equal to 2, positioned between the first and second guide bar patterns; and
second array board patterns including third and fourth guide bar patterns spaced apart from each other, and M second unit board patterns, where 1≦M<N, positioned between the third and fourth guide bar patterns.

2. The working panel of claim 1, wherein the N first unit board patterns are consecutively arranged in a lengthwise direction of the first guide bar patterns, and the M second unit board patterns are consecutively arranged in a lengthwise direction of the third guide bar pattern.

3. The working panel of claim 2, wherein opposite ends of the N first unit board patterns are connected to the first and second guide bar patterns, and opposite ends of the M second unit board patterns are connected to the third and fourth guide bar patterns, respectively.

4. The working panel of claim 2, wherein neighboring ones of the N first unit board patterns are arranged to be spaced apart from each other, and neighboring ones of the M second unit board patterns are arranged to be spaced apart from each other.

5. The working panel of claim 1, wherein the first unit board patterns and the second unit board patterns have the same patterns.

6. The working panel of claim 1, wherein the first and second guide bar patterns are longer than the third and fourth guide bar patterns.

7. The working panel of claim 1, wherein an interval between the first and second guide bar patterns is the same as an interval between the third and fourth guide bar patterns.

8. The working panel of claim 1, wherein a plurality of the first array board patterns are arranged in the first region, and one or more of the second array board patterns are arranged in the second region.

9. The working panel of claim 1, wherein a third array board pattern is further arranged in the second region, and the third array board pattern includes fifth and sixth guide bar patterns facing each other and less than N third unit board patterns positioned between the fifth and sixth guide bar patterns.

10. The working panel of claim 1, wherein N is the number of unit boards included in a unit array board provided in a surface mounting technology (SMT) process.

11. A working panel set comprising:
first to Lth working panels, where L is a natural number greater than or equal to 2, wherein the kth one of the working panels, where 1≦k≦L, comprises:
first array board patterns including a first guide bar pattern and N first unit board patterns consecutively arranged in the lengthwise direction of the first guide bar pattern, where N is a natural number greater than or equal to 2; and
second array board patterns including a second guide bar pattern and M(k) second unit board patterns, where 1≦M(k)<N, consecutively arranged in the lengthwise direction of the second guide bar pattern, and
$${\sum }_{k = 1}^{L} M ( k ) = N .$$

12. The working panel set of claim 11, wherein one end of each of the N first unit board patterns is connected to the first guide bar pattern, and one end of each of the M second unit board patterns is connected to the second guide bar pattern.

13. The working panel set of claim 11, wherein neighboring ones of the N first unit board patterns are arranged to be spaced apart from each other, and neighboring ones of the M(k) second unit board patterns are arranged to be spaced apart from each other.

14. The working panel set of claim 11, wherein the first guide bar pattern is longer than the second guide bar pattern.

15. The working panel set of claim 11, wherein N is the number of unit boards included in a unit array board provided in a surface mounting technology (SMT) process.

16. A working panel comprising:
a first region;
a second region;
a plurality of first array board patterns in the first region, each of the first array board patterns having a first guide bar pattern and N first unit board patterns, where N is a natural number greater than or equal to 2, connected to the first guide bar pattern;
a plurality of second array board patterns in the second region, each of the plurality of second array board patterns having a second guide bar pattern and M second unit board patterns, where 1≦M<N, connected to the second guide bar pattern.

17. The working panel of claim 16, wherein the N first unit board patterns are consecutively arranged in a lengthwise direction of the first guide bar patterns, and the M second unit board patterns are consecutively arranged in a lengthwise direction of the second guide bar pattern.

18. The working panel of claim 17, wherein each of the plurality of first array board patterns comprises a third guide bar pattern and each of the plurality of second array board patterns comprises a fourth guide bar pattern.

19. The working panel of claim 18, wherein opposite ends of the N first unit board patterns are connected to the first and third guide bar patterns, and opposite ends of the M second unit board patterns are connected to the second and fourth guide bar patterns, respectively.

20. The working panel of claim 17, wherein neighboring ones of the N first unit board patterns are arranged to be spaced apart from each other, and neighboring ones of the M second unit board patterns are arranged to be spaced apart from each other.
